(19) United States
(12) Patent Application Publication
(10) Pub. No.: US 2025/0126932 A1
(43) Pub. Date: Apr. 17, 2025

(54) MICRO LIGHT-EMITTING DIODE AND DISPLAY PANEL

(71) Applicant: HKC CORPORATION LIMITED, SHENZHEN (CN)

(72) Inventors: Guangjia WANG, SHENZHEN (CN); Junfeng XIE, SHENZHEN (CN)

(73) Assignee: HKC CORPORATION LIMITED, SHENZHEN (CN)

(21) Appl. No.: 18/888,174

(22) Filed: Sep. 18, 2024

(30) Foreign Application Priority Data
Oct. 12, 2023 (CN) 202311318989.6

(51) Int. Cl. H01L 33/08; H01L 25/075; H01L 33/38

(52) U.S. Cl. CPC H10H 20/813; H01L 25/0753; H10H 20/831

(57) ABSTRACT

A micro light-emitting diode and a display panel. The micro light-emitting diode includes a P-type semiconductor layer; a first light-emitting layer, disposed on a side of the P-type semiconductor layer; a second light-emitting layer, disposed on another side of the P-type semiconductor layer opposite to the first light-emitting layer; a first N-type semiconductor layer, disposed on a side of the first light-emitting layer away from the P-type semiconductor layer; a second N-type semiconductor layer, disposed on a side of the second light-emitting layer away from the P-type semiconductor layer; a P electrode, electrically connected to the P-type semiconductor layer; a first N electrode, connected to the first N-type semiconductor layer; and a second N electrode, connected to the second N-type semiconductor layer. Two light-emitting structures are formed.

### CROSS REFERENCE

The present disclosure claims priority of Chinese Patent Application No. 202311318989.6, filed on Oct. 12, 2023, the entire contents of which are hereby incorporated by reference in their entirety.

### TECHNICAL FIELD

The present disclosure relates to the field of display technologies, and more specifically to a micro light-emitting diode and display panel.

### BACKGROUND

Micro Light-emitting Diode (Micro-LED) has the advantages of high brightness, high contrast, high color gamut, high resolution, fast response time, energy saving, low power consumption, etc., which is regarded as the new direction of display revolution technology.

At present, the main constraint to the development of Micro-LED is the difficulty of mass transfer. Commonly applied mass transfer technologies include precise pick-and-release transfer technology, self-assembly technology, roller transfer technology, and laser stripping technology. Among them, the self-assembly technology may greatly improve the transfer efficiency, but the transfer yield is very low.

FIG. 1 illustrates a fluid self-assembly technology with shape complementary, where Micro-LEDs are assembled by automatic shape recognition and deposition of trapezoidal chips into matched trapezoidal holes of a target substrate under the effect of gravity and fluid propulsion. The disadvantage of this technology is that the Micro-LEDs may not be completely just right to snap into the corresponding trapezoidal grooves, which greatly reduces the transfer yield.

### SUMMARY OF THE DISCLOSURE

The main technical problem solved in the present disclosure is to provide a micro light-emitting diode and a display panel.

In a first aspect, the present disclosure provides a micro light-emitting diode, including: a P-type semiconductor layer; a first light-emitting layer, disposed on a side of the P-type semiconductor layer; a second light-emitting layer, disposed on another side of the P-type semiconductor layer opposite to the first light-emitting layer; a first N-type semiconductor layer, disposed on a side of the first light-emitting layer away from the P-type semiconductor layer; a second N-type semiconductor layer, disposed on a side of the second light-emitting layer away from the P-type semiconductor layer; a P electrode, electrically connected to the P-type semiconductor layer; a first N electrode, connected to the first N-type semiconductor layer; and a second N electrode, connected to the second N-type semiconductor layer; wherein the P-type semiconductor layer, the first light-emitting layer, the first N-type semiconductor layer, the P electrode, and the first N electrode form a first light-emitting structure; the P-type semiconductor layer, the second light-emitting layer, the second N-type semiconductor layer, the P electrode, and the second N electrode form a second light-emitting structure.

In a second aspect, the present disclosure provides a display panel, including the micro light-emitting diode as above and a substrate; wherein the substrate defines a plurality of recesses, and each recess is arranged with a first magnetic electrode opposite to the P electrode and a second magnetic electrode opposite to the first N electrode and/or the second N electrode.

### BRIEF DESCRIPTION OF THE DRAWINGS

In order to more clearly illustrate the technical solutions in the embodiments of the present disclosure, the accompanying drawings to be used in the description of the embodiments will be briefly introduced below, and it will be obvious that the accompanying drawings in the following description are only some of the embodiments of the present disclosure, and other accompanying drawings can be obtained according to these drawings for the those skilled in the art, without any creative labor.

FIG. 1 shows a fluid self-assembly technique with shape complementary in the related art.

FIG. 2 is a schematic structural view of a micro light-emitting diode according to some embodiments of the present disclosure.

FIG. 3 is a schematic structural view of a micro light-emitting diode according to a first implementation of the present disclosure.

FIG. 4 is a top view structural schematic view of a micro light-emitting diode according to a second implementation of the present disclosure.

FIG. 5 is a top view structural schematic view of a micro light-emitting diode according to a third implementation of the present disclosure.

FIG. 6 is a schematic structural view of a conventional micro light-emitting diode in the related art.

FIG. 7 is a schematic structural view of a display panel according to a first implementation of the present disclosure.

FIG. 8 is a schematic structural view of a micro light-emitting diode according to a fourth implementation of the present disclosure.

FIG. 9 is a schematic structural view of a micro light-emitting diode according to a fifth implementation of the present disclosure.

FIG. 10 is a schematic structural view of a display panel according to a second implementation of the present disclosure.

FIG. 11 is a schematic structural view of a micro light-emitting diode according to a sixth implementation of the present disclosure.

FIG. 12 is a schematic structural view of a display panel according to a third implementation of the present disclosure.

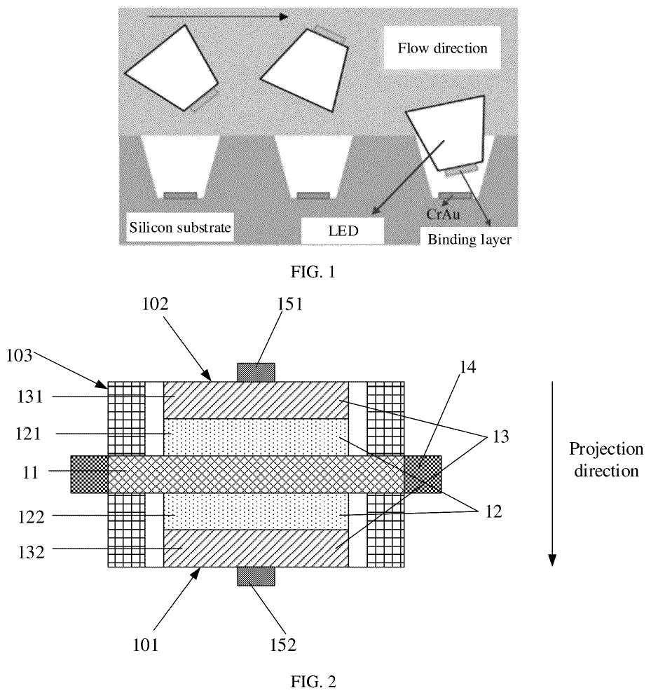

### DETAILED DESCRIPTION

The technical solutions in the embodiments of the present disclosure will be clearly and completely described below in conjunction with the accompanying drawings in the embodiments of the present disclosure, and it is clear that the embodiments described are only a part of the embodiments of the present disclosure and not all of the embodiments. Based on the embodiments in the present disclosure, all other embodiments obtained by those skilled in the art without making creative labor are within the scope of protection of the present disclosure.

The terms used in the embodiments of the present disclosure are intended solely for the purpose of describing particular embodiments and are not intended to limit the present disclosure. The singular forms of “a”, “said”, and “the” used in the embodiments and the appended claims of the present disclosure are intended to encompass the plural form, unless other meanings are clearly indicated above. The terms of “plurality” generally encompasses at least two, but does not preclude the inclusion of at least one.

It should be understood that the terms “comprising”, “including”, or any other variations thereof, as used herein, are intended to encompass non-exclusive inclusion, such that a process, method, article, or apparatus that includes a set of elements includes not only those elements but also other elements that are not explicitly listed or that are inherent to such process, method, article, or apparatus, or further includes elements that are inherent to such process, method, article, or apparatus. Without further limitation, the fact that an element is defined by the phrase “including . . . ” does not exclude the existence of another identical element in the process, method, article, or apparatus including the element.

It should be noted that when the embodiments of the present disclosure involve directional indications (e.g., up, down, left, right, forward, backward . . . ), the directional indications are only intended to explain a relative positional relationship, movement, etc., between components in a particular attitude (as shown in the accompanying drawings), and if the particular attitude changes, the directional indications change accordingly.

Reference to “embodiments” herein means that particular features, structures, or characteristics described in conjunction with the embodiments may be included in at least one embodiment of the present disclosure. The presence of the phrase at various points in the specification does not necessarily refer to the same embodiments or to separate or alternative embodiments that are mutually exclusive of other embodiments. It is understood by those skilled in the art, both explicitly and implicitly, that the embodiments described herein may be combined with other embodiments.

The present disclosure provides a micro light-emitting diode, with specific reference to FIG. 2, which is a schematic structural view of a micro light-emitting diode according to some embodiments of the present disclosure. As shown in FIG. 2, the micro light-emitting diode includes: a P-type semiconductor layer 11, a first light-emitting layer 121 and a second light-emitting layer 122, a first N-type semiconductor layer 131 and a second N-type semiconductor layer 132, and a P electrode 14 and an N electrode.

The first light-emitting layer 121 and the second light-emitting layer 122 are disposed on two side surfaces of the P-type semiconductor layer 11, respectively.

The first N-type semiconductor layer 131 and the second N-type semiconductor layer 132 are disposed on a side surface of the light-emitting layer (including the first light-emitting layer and the second light-emitting layer) away from the P-type semiconductor layer 11.

The P electrode 14 protrudes from a surface of the micro light-emitting diode and is connected to the P-type semiconductor layer 11, and the N electrode protrudes from another surface of the micro light-emitting diode and is connected to the N-type semiconductor layer. The N electrode includes a first N electrode 151 and a second N electrode 152, the first N electrode 151 is connected to the first N-type semiconductor layer 131, and the second N electrode 152 is connected to the second N-type semiconductor layer 132.

The P-type semiconductor layer 11, the first light-emitting layer 121, the first N-type semiconductor layer 131, the P electrode 14, and the first N electrode 151 form a first light-emitting structure. The P-type semiconductor layer 11, the second light-emitting layer 122, the second N-type semiconductor layer 132, the P electrode 14, and the second N electrode 152 form a second light-emitting structure. The first light-emitting structure and the second light-emitting structure share at least the P-type semiconductor layer 11, and in specific embodiments may further share the P electrode 14. The light-emitting structure may be a diode or a MOS tube, and the light-emitting layer may include a hole-injection layer, a hole-transporting layer, and an organic light-emitting layer, etc., which is not limited herein.

In the embodiments, by forming the symmetrical two light-emitting structures in the micro light-emitting diode, and, by making each of the P electrode and the N electrode protruding from a corresponding surface of a corresponding light-emitting structure, that is, from the surfaces of the micro light-emitting diode, the probability of the P electrode or the N electrode on the corresponding light-emitting structure coming into contact with a corresponding magnetic electrode on the substrate may be increased, and the contact area of the P electrode and N electrode with the magnetic electrodes on the substrate may be increased. Compared to the batch transfer method of single electrode positioning, the micro light-emitting diode in the present embodiments improves the batch transfer rate of transferring the micro light-emitting diode to the substrate.

It is noted that in some embodiments, the P-type semiconductor layer 11 is a P-GaN material, the N-type semiconductor layer 13 (including the first N-type semiconductor layer 131 and the second N-type semiconductor layer 132) is an N-GaN material, the P electrode is a P-type electrode, and the N electrode is an N-type electrode. In other embodiments, the materials of the P-type semiconductor layer 11 and the N-type semiconductor layer 13 may be interchanged, i.e., the P-type semiconductor layer 11 may be an N-GaN material, and the N-type semiconductor layer 13 is a P-GaN material, in which case the P electrode is an N-type electrode and the N electrode is a P-type electrode, which is not limited herein. The light-emitting structure may be an NMOS tube or a PMOS tube, specifically related to the setting order of the P-type semiconductor layer 11 and the N-type semiconductor layer 13, without limitation herein.

In the embodiments, the formed micro light-emitting diode is of a columnar structure including a bottom surface 101 and a top surface 102, and a column sidewall surface 103 disposed between the bottom surface 101 and the top surface 102. A positive projection of the bottom surface 101 on a vertical projection plane of the micro light-emitting diode is coincident with a positive projection of the top surface 102 on the vertical projection plane of the micro light-emitting diode. Specifically, when the P-type semiconductor layer 11 is circular on the vertical projection plane, the formed micro light-emitting diode is a cylinder, and when the P-type semiconductor layer 11 is polygonal (quadrilateral, pentagonal, etc.) on the vertical projection plane, the formed micro light-emitting diode is a polygonal column. Therefore, the shape of the column of the micro light-emitting diode is not limited herein.

The following is a specific description of the micro light-emitting diode in the form of a cylinder as an example.

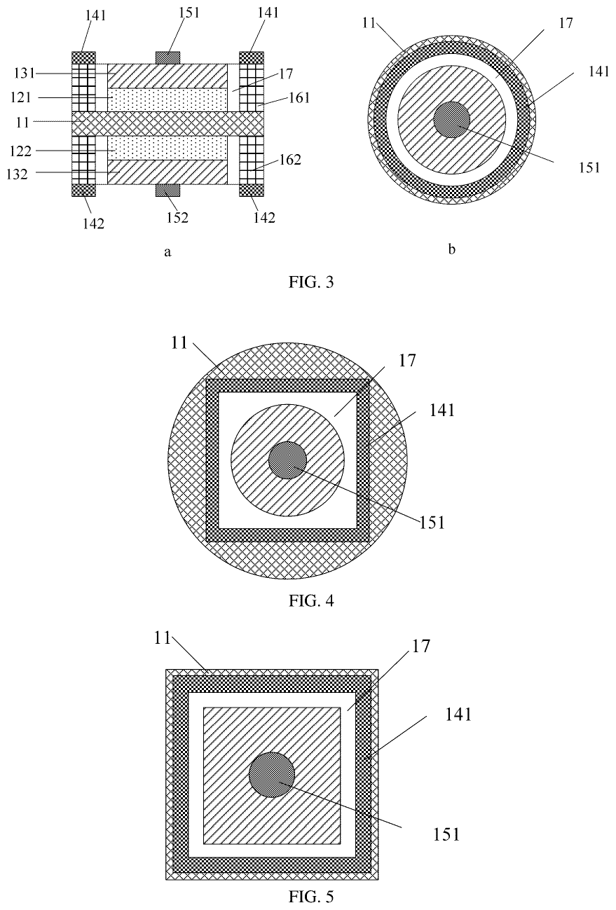

In some embodiments, the P electrode includes a first P electrode and a second P electrode. Specifically, referring to FIG. 3, FIG. 3 is a schematic structural view of a micro light-emitting diode according to a first implementation of the present disclosure. The left figure “a” in FIG. 3 is a side view or cross-sectional view of the micro light-emitting diode, and the right figure “b” is a schematic diagram of a top view structure of the micro light-emitting diode. As shown in FIG. 3, the P electrode includes a first P electrode 141 and a second P electrode 142, and the first P electrode 141 is disposed on a plane where the first N electrode 151 is located. The second P electrode 142 is disposed on a plane where the second N electrode 152 is located, that is, the first P electrode 141 is disposed on the same side and on the same plane as the first N electrode 151, and the second P electrode 142 is disposed on the same side and on the same plane as the second N electrode 152, so as to realize that the first N electrode 151 is in contact with a corresponding magnetic electrode on the substrate while the first P electrode 141 is also in contact with a corresponding magnetic electrode on the substrate, and further, realize that the second N electrode 152 is in contact with a corresponding magnetic electrode on the substrate while the second P electrode 142 is also in contact with a corresponding magnetic electrode on the substrate. In this way, the first P electrode 141 and the second P electrode 142 as well as the first N electrode 151 and the second N electrode 152 are able to protrude out of the surface of the micro light-emitting diode, thereby increasing the contact area between the electrode (including the P electrode and the N electrode) on a side of the micro light-emitting diode and a corresponding magnetic electrode on the substrate. Specifically, the first P electrode 141 and the first N electrode 151 are arranged on the top surface of the columnar micro light-emitting diode, and the second P electrode 142 and the second N electrode 152 are arranged on the bottom surface of the columnar micro light-emitting diode.

Further, in order to cause the first P electrode 141 and the first N electrode 151 to be disposed on the same plane, a first metal layer 161 is arranged between the first P electrode 141 and the P-type semiconductor layer 11, for connecting the first P electrode 141 and the P-type semiconductor layer 11 through the first metal layer 161. Similarly, a second metal layer 162 is arranged between the second P electrode 142 and the P-type semiconductor layer 11, for connecting the second P electrode 141 and the P-type semiconductor layer 11 through the second metal layer 162. In the embodiments, the first metal layer 161 is spaced apart from the first light-emitting layer 121 and the first N-type semiconductor layer 131, and the second metal layer 162 is spaced apart from the second light-emitting layer 122 and the second N-type semiconductor layer 132, such that the second P electrode 142 and the second N electrode 152 are spaced apart to avoid short-circuiting of the P electrode and the N electrode. In some embodiments, the metal layer may be spaced from the light-emitting layer and the N-type semiconductor layer by an insulating layer 17, specifically, the insulating layer 17 is disposed between the first metal layer 161 and the first light-emitting layer 121 as well as the first N-type semiconductor layer 131 to space the first metal layer 161 from the first light-emitting layer 121 and the first N-type semiconductor layer 131; the insulating layer 17 is further disposed between the second metal layer 162 and the second light-emitting layer 122 as well as the second N-type semiconductor layer 132 to space the second metal layer 162 from the second light-emitting layer 122 and the second N-type semiconductor layer 132. In other embodiments, the metal layer may be spaced apart by other materials or air, which is not limited herein.

In the embodiments, the thickness of the first metal layer 161 is the same as a sum of the thicknesses of the first light-emitting layer 121 and the first N-type semiconductor layer 131, such that the first P electrode 141 is disposed on the same plane as the first N electrode 151. The thickness of the second metal layer 162 is the same as a sum of the thicknesses of the second light-emitting layer 122 and the second N-type semiconductor layer 132, such that the second P electrode 142 is disposed on the same plane as the second N electrode 152. The thicknesses of the first metal layer 161 and the second metal layer 162 may be different, i.e., the first light-emitting structure and the second light-emitting structure may not be identical, which is not limited herein.

In the embodiments, the P-type semiconductor layer 11 protrudes from the light-emitting layer 12 and the N-type semiconductor layer 13. Specifically, a length or radius of the positive projection of the P-type semiconductor layer 11 on the vertical projection plane is greater than a length or radius of the positive projection of each of the light-emitting layer 12 and the N-type semiconductor layer 13, such that the P-type semiconductor layer 11 protrudes from the light-emitting layer 12 and the N-type semiconductor layer 13, and thus opposite sides of a protruding portion of the P-type semiconductor layer 11 are arranged with the first metal layer 161 and the second metal layer 162, respectively.

In the embodiments, the first N electrode 151 and the second N electrode 152 are disposed close to a core position of the micro light-emitting diode; the first P electrode 141 is disposed around the first N electrode 151, and the second P electrode 142 is disposed around the second N electrode 152. Specifically, referring to the illustration shown in b in FIG. 3, each of the first N electrode 151 and the second N electrode 152 is disposed close to a center position of the vertical projection plane of the micro light-emitting diode. Specifically, when the micro light-emitting diode is a cylinder, each of the first N electrode 151 and the second N electrode 152 is disposed close to a circular center position of the vertical projection plane of the micro light-emitting diode. The positive projections of the first N electrode 151 and the second N electrode 152 on the vertical projection plane may not overlap. The vertical projection plane includes the top surface and the bottom surface of the micro light-emitting diode, the first N electrode 151 is disposed on the center position of the top surface, and the second N electrode 152 is disposed on the center position of the bottom surface. The positive projection of each of the first N electrode 151 and the second N electrode 152 on the vertical projection plane may be circular or square or other polygonal shapes, without limitation herein. The first P electrode 141 is disposed around the first N electrode 151 and spaced apart from the first N electrode 151; and the second P electrode 142 is disposed around the second N electrode 152. Specifically, the positive projection of each of the first P electrode 141 and the second P electrode 142 on the vertical projection plane is circular.

In other embodiments, each of the first P electrode 141 and the second P electrode 142 may be a square ring. Specifically referring to FIG. 4 and FIG. 5, FIG. 4 is a top view structural schematic view of a micro light-emitting diode according to a second implementation of the present disclosure, and FIG. 5 is a top view structural schematic view of a micro light-emitting diode according to a third implementation of the present disclosure. The micro light-emitting diode may be a cylinder as shown in FIG. 4, and the micro light-emitting diode may be a quadrilateral column (including a square and a rectangle, etc.) as shown in FIG. 5, and in other embodiments, the micro light-emitting diode may be a pentagonal column or a hexagonal column, which will not be enumerated herein. The cross-sectional views of the micro light-emitting diode in the second implementation and the third implementation are the same as those in the first implementation, as shown in a in FIG. 3, which is not repeated herein.

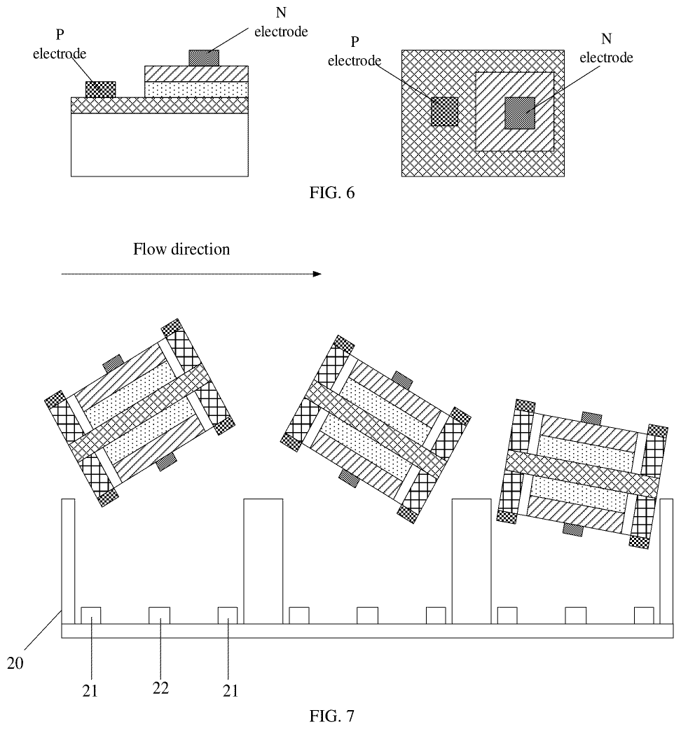

The present disclosure further provides a schematic structural view of a micro light-emitting diode in related art. Referring specifically to FIG. 6, FIG. 6 is a schematic structural view of a conventional micro light-emitting diode in the related art. The left side of FIG. 6 is a schematic diagram of a cross-section structure of the micro light-emitting diode in the related art, and the right side of FIG. 6 is a schematic diagram of a top view structure of the micro light-emitting diode in the related art. In the related art, the P electrode and the N electrode on the micro light-emitting diode are not disposed on the same plane, and thus, only one electrode can be involved in the alignment. Secondly, the P electrode is not arranged around the N electrode.

In the present disclosure, both the P electrode and the N electrode can participate in the alignment, and the P electrode is arranged around the N electrode to form a ring-shaped alignment area, such that the alignment area of the P electrode is much larger than the alignment area of the P electrode in the related art.

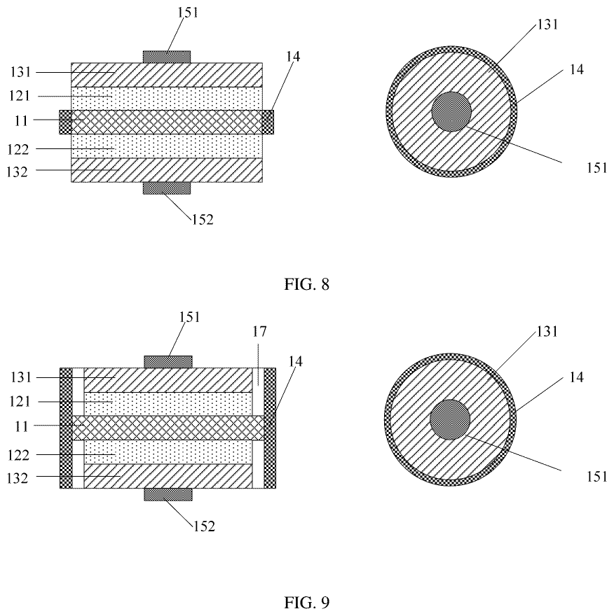

The present disclosure further provides a display panel, referring to FIG. 7, FIG. 7 is a schematic structural view of a display panel according to a first implementation of the present disclosure. As shown in FIG. 7, the display panel includes a substrate 20, multiple recesses are defined on the substrate 20, and each of the recesses is configured to arrange a first magnetic electrode 21 and a second magnetic electrode 22. The first magnetic electrode 21 is arranged opposite to the P electrode, that is, the first magnetic electrode 21 is also arranged in the shape of a circle on a bottom surface of a corresponding recess. The second magnetic electrode 22 is arranged opposite to the first N electrode or the second N electrode, that is, the second magnetic electrode 22 is arranged on a circular center position on the bottom surface of the recess, forming an alignment with a corresponding one of the first N electrode and the second N electrode. The recess is configured for placing the micro light-emitting diode in the above embodiments, and when multiple the micro light-emitting diodes are placed into the corresponding recesses respectively, they form an electrical connection with the first magnetic electrodes 21 and the second magnetic electrodes 22 in the recesses, so as to form the display panel in which the micro light-emitting diodes are driven to emit light by a backplane. The first magnetic electrode 21 and the second magnetic electrode 22 are metal electrodes forming an alignment with the P electrodes and the N electrodes. FIG. 7 further illustrates a dynamic process in which the micro light-emitting diodes are sequentially placed into the recesses driven by a fluid flow. The micro light-emitting diodes randomly fall into the recesses of the substrate 20 under the impetus of the carrier fluid, and since each micro light-emitting diode has two light-emitting structures, either of the two light-emitting structures can make contact with the metal electrodes, which may greatly improve the possibility of the electrodes of the micro light-emitting diodes making contact with the electrodes on the substrate 20. In this way, the electrode contact area is increased, and thus the transfer yield is improved.

In the above embodiments, the P electrodes are arranged on opposite side surfaces of the P-type semiconductor layer, that is, the bottom surface and the top surface of the micro light-emitting diode. In other embodiments, the P electrodes may be arranged on the column sidewall surface of the micro light-emitting diode. Referring to FIG. 8, FIG. 8 is a schematic structural view of a micro light-emitting diode according to a fourth implementation of the present disclosure, in which case the P electrode 14 is arranged on a surface of the P-type semiconductor layer 11 on the column sidewall surface of the micro light-emitting diode. A cross-sectional view of the micro light-emitting diode is shown on the left in FIG. 8, and a top view of the micro light-emitting diode is shown on the right. In the embodiments, the first N electrode 151 is arranged on a surface of the first N-type semiconductor layer 131 away from the P-type semiconductor layer 11, that is, on the top surface of the micro light-emitting diode, and the second N electrode 152 is arranged on a surface of the second N-type semiconductor layer 132 away from the P-type semiconductor layer 11, that is, on the bottom surface of the micro light-emitting diode. The P electrode 14 is arranged only on the side surface of the P-type semiconductor layer 11, spaced apart from the light-emitting layer 12 and the N-type semiconductor layer 13, and thereby spaced apart from the N electrode to avoid a short circuit connection. The N electrode (including the first N electrode and the second N electrode) may be arranged on a whole surface, that is, arranged on the whole surface of the N-type semiconductor layer 13, which is not limited herein.

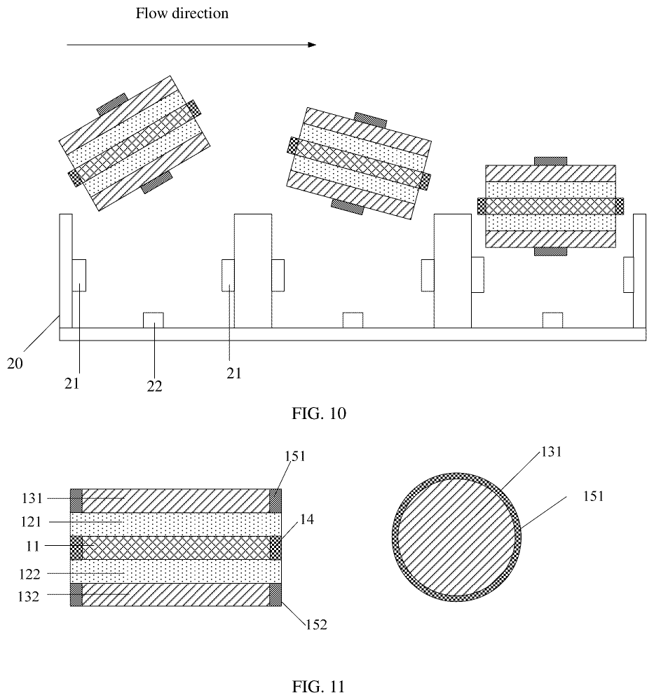

Further, referring to FIG. 9, FIG. 9 is a schematic structural view of a micro light-emitting diode according to a fifth implementation of the present disclosure. A cross-sectional view of the micro light-emitting diode is shown on the left, and a top view of the micro light-emitting diode is shown on the right. As shown in FIG. 9, an insulating layer 17 is arranged on a surface of the first light-emitting layer 121, the first N-type semiconductor layer 131, the second light-emitting layer 122, and the second N-type semiconductor layer 132 on the column sidewall surface of the micro light-emitting diode, such that the P electrode 14 may be disposed on the entire column sidewall surface of the micro light-emitting diode. In the embodiments, the radius of the positive projection of the P-type semiconductor layer 11 on the vertical projection plane is greater than the radius of the positive projection of each of the light-emitting layer 12 and the N-type semiconductor layer 13, such that the P-type semiconductor layer 11 partially protrudes from the light-emitting layer and the N-type semiconductor layer, and the insulating layer 17 is arranged on the protruding portion to ensure that the column sidewall surface is flat. In other embodiments, the radius of the positive projection of the P-type semiconductor layer 11 on the vertical projection plane is equal to the radius of the positive projection of each of the light-emitting layer 12 and the N-type semiconductor layer 13, and the thickness of the P electrode on the P-type semiconductor layer 11 is greater than the thickness of the P electrode on the light-emitting layer and the N-type semiconductor layer, which also ensures that the column sidewall surface is flat. In the embodiments, the P electrode 14 is spaced from the light-emitting layer and the N-type semiconductor layer by the insulating layer 17, such that the contact area of the P electrode 14 is enlarged, which greatly reduces the resistance during the transfer process and improves the transfer efficiency.

In the fourth and fifth implementations, the P electrode is arranged on the column sidewall surface of the micro light-emitting diode, and the N electrode is arranged on the top and bottom surfaces of the micro light-emitting diode. The present disclosure further provides a display panel, with specific reference to FIG. 10, FIG. 10 is a schematic structural view of a display panel according to a second implementation of the present disclosure. As shown in FIG. 10, the display panel includes a substrate 20, and multiple recesses are defined on the substrate 20; a first magnetic electrode 21 is formed on a side wall of each recess, and a second magnetic electrode 22 is formed on a bottom wall of each recess. The first magnetic electrode 21 is disposed opposite to the P electrode, and the second magnetic electrode 22 is disposed opposite to the first N electrode or the second N electrode. The first magnetic electrode 21 may be set in the same shape as the P electrode or may be different, and specifically may be a continuous circular shape, an interrupted circular shape, or two point shapes or line segments set symmetrically, without limitation herein.

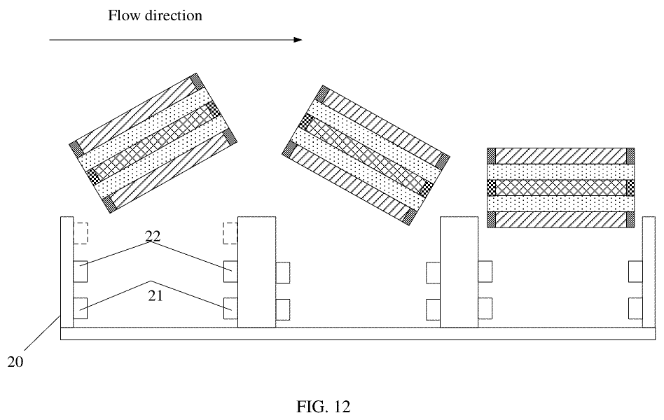

The present disclosure further provides a sixth implementation of the micro light-emitting diode, specifically referring to FIG. 11, FIG. 11 is a schematic structural view of a micro light-emitting diode according to a sixth implementation of the present disclosure. As shown in FIG. 11, the P electrode 14 is disposed on a surface of the P-type semiconductor layer 11 on the column sidewall surface of the micro light-emitting diode. The first N electrode 151 is disposed on a surface of the first N-type semiconductor layer 131 on the column sidewall surface of the micro light-emitting diode, and the second N electrode 152 is disposed on a surface of the second N-type semiconductor layer 132 on the column sidewall surface of the micro light-emitting diode. The P electrode 14 and the first N electrode 151 and the second N electrode 152 are all in the shape of a ring having the same inner radius, and the outer radius may or may not be the same. Specifically, the radius of each of the first light-emitting layer 121 and the second light-emitting layer 122 is equal to a sum of the radius of the P-type semiconductor layer 11 and the thickness of the P electrode 14, so as to make the column sidewall surface flat. In other embodiments, the radius of the P-type semiconductor layer 11 may be the same as the radius of the N-type semiconductor layer, so as to make the P electrode and N electrode protrude out of the column sidewall surface. The present disclosure makes no limitation in this regard.

The present disclosure further provides a third implementation of the display panel, specifically referring to FIG. 12, FIG. 12 is a schematic structural view of a display panel according to a third implementation of the present disclosure. The display panel includes a substrate 20, and multiple recesses are defined on the substrate 20; and each of the recesses is configured to arrange a first magnetic electrode 21 and a second magnetic electrode 22. Specifically, the first magnetic electrode 21 is arranged opposite to the P electrode, and the second magnetic electrode 22 is arranged opposite to the first N electrode or the second N electrode. Specifically, as shown in FIG. 11, a sidewall of the recess is arranged with the first magnetic electrode 21 and the second magnetic electrode 22. In some embodiments, a third magnetic electrode may further be arranged on the sidewall of the recess, and the third magnetic electrode is arranged opposite to the other of the first N electrode and the second N electrode, which is not limited herein. The recess is configured for placing the micro light-emitting diode described in the above embodiments. The substrate may be a driving substrate to form a display panel with the micro light-emitting diode for light-emitting display.

The beneficial effect of the present disclosure is that: by forming the symmetrical two light-emitting structures in the micro light-emitting diode, the contact probability of the P electrode or N electrode on either set of light-emitting structures with the magnetic electrode on the substrate is increased; further, at least one set of the P electrodes is of circular design to increase the contact area of the P electrode with the magnetic electrode on the substrate. In comparison to the batch transfer method of single electrode positioning, the micro light-emitting diode in the present embodiments improves the batch transfer rate of transferring the micro light-emitting diode to the substrate.

The above is only some embodiments of the present disclosure, and is not intended to limit the scope of the present disclosure. Any equivalent structure or equivalent process transformation utilizing the contents of the specification of the present disclosure and the accompanying drawings, or directly or indirectly utilized in other related technical fields, are all reasonably included in the scope of the present disclosure.

What is claimed is:

1. A micro light-emitting diode, comprising:
a P-type semiconductor layer;
a first light-emitting layer, disposed on a side of the P-type semiconductor layer;
a second light-emitting layer, disposed on another side of the P-type semiconductor layer opposite to the first light-emitting layer;
a first N-type semiconductor layer, disposed on a side of the first light-emitting layer away from the P-type semiconductor layer;
a second N-type semiconductor layer, disposed on a side of the second light-emitting layer away from the P-type semiconductor layer;
a P electrode, electrically connected to the P-type semiconductor layer;
a first N electrode, connected to the first N-type semiconductor layer; and
a second N electrode, connected to the second N-type semiconductor layer;
wherein the P-type semiconductor layer, the first light-emitting layer, the first N-type semiconductor layer, the P electrode, and the first N electrode form a first light-emitting structure; the P-type semiconductor layer, the second light-emitting layer, the second N-type semiconductor layer, the P electrode, and the second N electrode form a second light-emitting structure.

2. The micro light-emitting diode according to claim 1, being of a columnar structure comprising: a bottom surface and a top surface, and a column sidewall surface disposed between the bottom surface and the top surface; wherein a positive projection of the bottom surface on a vertical projection plane of the micro light-emitting diode is coincident with a positive projection of the top surface on the vertical projection plane of the micro light-emitting diode.

3. The micro light-emitting diode according to claim 2, wherein the P electrode comprises a first P electrode and a second P electrode; the first P electrode is disposed on a plane where the first N electrode is located, and the second P electrode is disposed on a plane where the second N electrode is located.

4. The micro light-emitting diode according to claim 3, wherein the first P electrode and the P-type semiconductor layer are connected through a first metal layer, and the first metal layer is spaced apart from the first light-emitting layer and the first N-type semiconductor layer; the second P electrode and the P-type semiconductor layer are connected through a second metal layer, and the second metal layer is spaced apart from the second light-emitting layer and the second N-type semiconductor layer.

5. The micro light-emitting diode according to claim 4, wherein the first metal layer is spaced from the first light-emitting layer and the first N-type semiconductor layer by an insulating layer, and the second metal layer is spaced from the second light-emitting layer and the second N-type semiconductor layer by the insulating layer.

6. The micro light-emitting diode according to claim 4, wherein a thickness of the first metal layer is the same as a sum of thicknesses of the first light-emitting layer and the first N-type semiconductor layer; a thickness of the second metal layer is the same as a sum of thicknesses of the second light-emitting layer and the second N-type semiconductor layer.

7. The micro light-emitting diode according to claim 3, wherein the first N electrode and the second N electrode are each disposed close to a core position of the micro light-emitting diode;
on the vertical projection plane, a positive projection of the first P electrode is disposed around a positive projection of the first N electrode, and a positive projection of the second P electrode is disposed around a positive projection of the second N electrode.

8. The micro light-emitting diode according to claim 2, wherein the P electrode is arranged on a surface of the P-type semiconductor layer on the column sidewall surface of the micro light-emitting diode.

9. The micro light-emitting diode according to claim 8, wherein an insulating layer is arranged on a surface of the first light-emitting layer, the first N-type semiconductor layer, the second light-emitting layer, and the second N-type semiconductor layer on the column sidewall surface of the micro light-emitting diode; the P electrode is disposed on all of the column sidewall surface of the micro light-emitting diode.

10. The micro light-emitting diode according to claim 8, wherein the first N electrode is disposed on a surface of the first N-type semiconductor layer on the column sidewall surface of the micro light-emitting diode, and the second N electrode is disposed on a surface of the second N-type semiconductor layer on the column sidewall surface of the micro light-emitting diode.

11. A micro light-emitting diode, being of a columnar structure comprising: a bottom surface and a top surface, and a column sidewall surface disposed between the bottom surface and the top surface; wherein a positive projection of the bottom surface on a vertical projection plane of the micro light-emitting diode is coincident with a positive projection of the top surface on the vertical projection plane of the micro light-emitting diode;
the micro light-emitting diode comprises:
a P-type semiconductor layer;
a first light-emitting layer, disposed on a side of the P-type semiconductor layer;
a second light-emitting layer, disposed on another side of the P-type semiconductor layer opposite to the first light-emitting layer;
a first N-type semiconductor layer, disposed on a side of the first light-emitting layer away from the P-type semiconductor layer;
a second N-type semiconductor layer, disposed on a side of the second light-emitting layer away from the P-type semiconductor layer;
a P electrode, electrically connected to the P-type semiconductor layer; wherein a number of the P electrode is one, and the P electrode is of an annular shape and is disposed on all of a surface of the P-type semiconductor layer exposed from the column sidewall surface;
a first N electrode, connected to the first N-type semiconductor layer; and
a second N electrode, connected to the second N-type semiconductor layer;
wherein the P-type semiconductor layer, the first light-emitting layer, the first N-type semiconductor layer, the P electrode, and the first N electrode form a first light-emitting structure; the P-type semiconductor layer, the second light-emitting layer, the second N-type semiconductor layer, the P electrode, and the second N electrode form a second light-emitting structure.

12. The micro light-emitting diode according to claim 11, wherein the first N electrode and the second N electrode are each disposed close to a core position of the micro light-emitting diode;
on the vertical projection plane, a positive projection of the P electrode is disposed around a positive projection of the first N electrode and a positive projection of the second N electrode.

13. The micro light-emitting diode according to claim 11, wherein an insulating layer is arranged on a surface of the first light-emitting layer, the first N-type semiconductor layer, the second light-emitting layer, and the second N-type semiconductor layer on the column sidewall surface of the micro light-emitting diode; the P electrode is disposed on all of the column sidewall surface of the micro light-emitting diode.

14. The micro light-emitting diode according to claim 13, wherein a gap is defined between the P electrode and each of the first light-emitting layer, the first N-type semiconductor layer, the second light-emitting layer, and the second N-type semiconductor layer; the insulating layer is filled in the gap.

15. A display panel, comprising the micro light-emitting diode according to claim 11 and a substrate; wherein the substrate defines a plurality of recesses, and each recess is arranged with a first magnetic electrode opposite to the P electrode and a second magnetic electrode opposite to the first N electrode and/or the second N electrode.

16. The display panel according to claim 15, wherein the first N electrode and the second N electrode are each disposed close to a core position of the micro light-emitting diode;
on the vertical projection plane, a positive projection of the P electrode is disposed around a positive projection of the first N electrode and a positive projection of the second N electrode.

17. The display panel according to claim 15, wherein an insulating layer is arranged on a surface of the first light-emitting layer, the first N-type semiconductor layer, the second light-emitting layer, and the second N-type semiconductor layer on the column sidewall surface of the micro light-emitting diode; the P electrode is disposed on all of the column sidewall surface of the micro light-emitting diode.

18. The micro light-emitting diode according to claim 17, wherein a gap is defined between the P electrode and each of the first light-emitting layer, the first N-type semiconductor layer, the second light-emitting layer, and the second N-type semiconductor layer; the insulating layer is filled in the gap.

19. A micro light-emitting diode, being of a columnar structure comprising: a bottom surface and a top surface, and a column sidewall surface disposed between the bottom surface and the top surface; wherein a positive projection of the bottom surface on a vertical projection plane of the micro light-emitting diode is coincident with a positive projection of the top surface on the vertical projection plane of the micro light-emitting diode;
the micro light-emitting diode comprises:
a P-type semiconductor layer;
a first light-emitting layer, disposed on a side of the P-type semiconductor layer;
a second light-emitting layer, disposed on another side of the P-type semiconductor layer opposite to the first light-emitting layer;
a first N-type semiconductor layer, disposed on a side of the first light-emitting layer away from the P-type semiconductor layer;
a second N-type semiconductor layer, disposed on a side of the second light-emitting layer away from the P-type semiconductor layer;
a P electrode, electrically connected to the P-type semiconductor layer;
a first N electrode, connected to the first N-type semiconductor layer; and
a second N electrode, connected to the second N-type semiconductor layer;
wherein the P electrode is disposed on a surface of the P-type semiconductor layer on the column sidewall surface of the micro light-emitting diode; the first N electrode is disposed on a surface of the first N-type semiconductor layer on the column sidewall surface of the micro light-emitting diode; and the second N electrode is disposed on a surface of the second N-type semiconductor layer on the column sidewall surface of the micro light-emitting diode;
wherein the P-type semiconductor layer, the first light-emitting layer, the first N-type semiconductor layer, the P electrode, and the first N electrode form a first light-emitting structure; the P-type semiconductor layer, the second light-emitting layer, the second N-type semiconductor layer, the P electrode, and the second N electrode form a second light-emitting structure.

20. The micro light-emitting diode according to claim 19, wherein each of the P electrode, the first N electrode, and the second N electrode is of an annular shape;
an inner radius of the P electrode, an inner radius of the first N electrode, and an inner radius of the second N electrode are the same.
